(19) United States
(12) Patent Application Publication
(10) Pub. No.: US 2024/0272207 A1
(43) Pub. Date: Aug. 15, 2024

(54) AC Current Sensor And Wireless Charging Chip

(71) Applicant: NANJING UNIVERSITY, Nanjing (CN)

(72) Inventors: Hao QIU, Nanjing (CN); Xusheng ZHANG, Nanjing (CN); Yi SHI, Nanjing (CN)

(73) Assignee: NANJING UNIVERSITY, Nanjing (CN)

(21) Appl. No.: 18/465,954

(22) Filed: Sep. 12, 2023

(30) Foreign Application Priority Data
Feb. 15, 2023 (CN) 202310115609.2

(51) Int. Cl. G01R 19/10; H02J 50/12

(52) U.S. Cl. CPC G01R 19/10; H02J 50/12

(57) ABSTRACT

Disclosed in the present application are an AC current sensor and a wireless charging chip. The AC current sensor includes an integrator circuit, a differentiator circuit, and a calibration circuit. The integrator circuit is configured to perform integration on a voltage on which filter processing is performed across an inductor in a TX coil. The differentiator circuit is configured to perform differentiation on a voltage on which filter processing is performed across a capacitor in the TX coil. The calibration circuit is configured to sample and compare output signals of the integrator circuit and the differentiator circuit, and adjust output results of the integrator circuit and the differentiator circuit until the output results are the same. In this case, the output result of the differentiator circuit may be used to calculation for a current flowing through the TX coil.

### CROSS-REFERENCE TO RELATED APPLICATIONS

The present application claims priority to Chinese Patent Application No. 202310115609.2, entitled “AC CURRENT SENSOR AND WIRELESS CHARGING CHIP”, filed with the China National Intellectual Property Administration (CNIPA) on Feb. 15, 2023, the entire disclosure of which is incorporated by reference in its entirety herein.

### FIELD OF THE INVENTION

The present application relates to the field of wireless power transmission, and in particular, to an AC current sensor and a wireless charging chip.

### BACKGROUND OF THE INVENTION

Charging of smart devices is gradually developing from wired charging to wireless charging. The principle of wireless charging is to implement power transmission through circuit coupling between a transmitter and a receiver. The transmitter is disposed in a wireless charging device, and the receiver is disposed in a smart device. The transmitter is provided with a transmitting coil (TX coil), and the receiver is provided with a receiving coil (RX coil). Whether the wireless charging device can accurately charge the smart device depends on whether the TX coil can be accurately coupled with the corresponding RX coil, furthermore, whether the coupling is accurate depends on whether current measurement for the RX coil in the receiver by the transmitter is accurate. The transmitter may also determine, through the current measurement, whether the receiver needs to be charged or whether charging is completed.

The transmitter may measure a current of the TX coil by providing an AC current sensor, and then calculate and obtain a current of the RX coil. The TX coil typically includes an inductor and a capacitor that are connected in series. A conventional AC current sensor may use a secondary coil to be close to the inductor and measure a current of the secondary coil. Since the current of the secondary coil is in direct proportion to a current of a primary coil, a current of the inductor may be obtained according to the current of the secondary coil and the proportion, and the current of the inductor may be used as the measured current of the TX coil.

However, this type of AC current sensor cannot be perform integration on due to reliance on the secondary coil for measurement, occupies a large area, and has a significant measurement deviation.

### SUMMARY OF THE INVENTION

The present application provides an AC current sensor and a wireless charging chip, which may be used to resolve a technical problem that a conventional AC current sensor has low accuracy in measuring a current of a TX coil and is difficult for integration.

According to a first aspect, an embodiment of the present application provides an AC current sensor, including:
an integrator circuit, configured to receive a first inductor voltage through a first input terminal of the integrator circuit, and perform integration on the first inductor voltage to generate a second inductor voltage, wherein the first inductor voltage is a voltage obtained by performing filtering processing on a voltage across an inductor in a TX coil, and the integrator circuit comprises a first adjustable resistor;
a differentiator circuit, configured to receive a first capacitor voltage through a first input terminal of the differentiator circuit, and perform differentiation on the first capacitor voltage to generate a second capacitor voltage, wherein the first capacitor voltage is a voltage obtained by performing filtering processing on a voltage across a capacitor in the TX coil, and the differentiator circuit comprises a second adjustable resistor; and
a calibration circuit, configured to generate a clock signal based on the first capacitor voltage, simultaneously adjust resistance values of the first adjustable resistor and the second adjustable resistor according to the clock signal, and compare a third inductor voltage with a third capacitor voltage in a real-time manner until the third inductor voltage is equal to the third capacitor voltage to complete calibration, wherein the third inductor voltage is obtained by performing peak sampling on the second inductor voltage, and the third capacitor voltage is obtained by performing peak sampling on the second capacitor voltage,
wherein after the calibration is completed, the second capacitor voltage output from the differentiator circuit is used to be converted into a current flowing through the TX coil according to a preset conversion relationship.

In combination with the first aspect, in a possible implementation of the first aspect, the calibration circuit includes:
a clock circuit, configured to generate a first clock signal, a second clock signal, a third clock signal, and a fourth clock signal based on the first capacitor voltage;
a logic circuit, having an output terminal coupled to a second input terminal of the integrator circuit and a second input terminal of the differentiator circuit, respectively, and configured to simultaneously adjust the resistance values of the first adjustable resistor and the second adjustable resistor according to the fourth clock signal;
a first sample-and-hold circuit, having a first input terminal coupled to an output terminal of the integrator circuit, and configured to perform peak sampling on the second inductor voltage according to the first clock signal and the second clock signal to obtain the third inductor voltage;
a second sample-and-hold circuit, having a first input terminal coupled to an output terminal of the differentiator circuit, and configured to perform peak sampling on the second capacitor voltage according to the first clock signal and the second clock signal to obtain the third capacitor voltage; and
a comparer, having a first input terminal coupled to an output terminal of the first sample-and-hold circuit and a second input terminal coupled to an output terminal of the second sample-and-hold circuit, and configured to compare the third inductor voltage with the third capacitor voltage in a real-time manner according to the third clock signal, and output a comparison result for indicating whether the third inductor voltage is equal to the third capacitor voltage.

In combination with the first aspect, in a possible implementation of the first aspect, the first adjustable resistor and the second adjustable resistor have a same structure, each including:
a fixed resistor and a plurality of controllable resistors, which are connected in series, wherein a resistance value of each of the controllable resistors is in a preset proportion to a resistance value of the fixed resistor; and
a plurality of adjustable switches in one-to-one correspondence to the plurality of controllable resistors, wherein the adjustable switches each are connected in parallel across the corresponding controllable resistors, and each of the adjustable switches comprises a control input terminal for receiving of a switch control signal and is turned on or off under control of the switch control signal.

In combination with the first aspect, in a possible implementation of the first aspect, the logic circuit includes a plurality of flip-flops and a plurality of logic gates, which are sequentially connected, and the plurality of flip-flops and the plurality of logic gates are in one-to-one correspondence to the plurality of the adjustable switches of the first adjustable resistor or the plurality of adjustable switches of the second adjustable resistor;
wherein each of the logic gates has a first input terminal coupled to a first output terminal of a corresponding one of the flip-flops, a second input terminal, and an output terminal of the logic gate is respectively coupled to a second input terminal of a next one of the logic gates and a first input terminal of one of the flip-flops corresponding to the next logic gate, wherein a second input terminal of a first one of the logic gates and a first input terminal of a corresponding one of the flip-flops are configured for receiving of a state signal output from the comparator; and
wherein each of the flip-flops has the first input terminal, a second input terminal configured for receiving of the fourth clock signal, a third input terminal configured for receiving of a first enable signal, the first output terminal, and a second output terminal coupled to the control input terminal of the corresponding adjustable switch configured for outputting of the switch control signal for the corresponding adjustable switch.

In combination with the first aspect, in a possible implementation of the first aspect, the first sample-and-hold circuit and the second sample-and-hold circuit have a same structure, each including a first flip-flop switch, a first operational amplifier, a second flip-flop switch, and a second operational amplifier;
wherein the first flip-flop switch has a first terminal configured for receiving of a corresponding second inductor voltage or second capacitor voltage, a second terminal coupled to a positive input terminal of the first operational amplifier, and a third terminal configured for receiving of the first clock signal; the first operational amplifier has the positive input terminal, a negative input terminal, and an output terminal to which the negative input terminal is coupled, the output terminal of the first operational amplifier being further coupled to a first terminal of the second flip-flop switch; the second flip-flop switch has the first terminal, a second terminal coupled to a positive input terminal of the second operational amplifier, and a third terminal configured for receiving of the second clock signal; and the second operational amplifier has the positive input terminal, a negative input terminal, and an output terminal to which the negative input terminal of the second operational amplifier is coupled, and the output terminal of the second operational amplifier is configured for outputting of a corresponding third inductor voltage or third capacitor voltage; and
wherein the second terminal of the first flip-flop switch is further connected to a first ground capacitor, and the second terminal of the second flip-flop switch is further connected to a second ground capacitor.

In combination with the first aspect, in a possible implementation of the first aspect, the integrator circuit further includes a first capacitor connected in series to the first adjustable resistor; and
an end of the first adjustable resistor away from the first capacitor and an end of the first capacitor away from the first adjustable resistor are together configured as the first input terminal of the integrator circuit, and a voltage across the first capacitor is configured as the second inductor voltage.

In combination with the first aspect, in a possible implementation of the first aspect, the differentiator circuit further includes a second capacitor connected in series to the second adjustable resistor; and
an end of the second adjustable resistor away from the second capacitor and an end of the second capacitor away from the second adjustable resistor are together configured as the first input terminal of the differentiator circuit, and a voltage across the second adjustable resistor is configured as the second capacitor voltage.

In combination with the first aspect, in a possible implementation of the first aspect, the AC current sensor further includes:
a first filter circuit, configured to perform attenuation, low-pass filtering, and subtraction on the voltage across the inductor in the TX coil, respectively, to obtain the first inductor voltage; and
a second filter circuit, configured to perform attenuation, low-pass filtering, and subtraction on the voltage across the capacitor in the TX coil, respectively, to obtain the first capacitor voltage.

In combination with the first aspect, in a possible implementation of the first aspect, the current flowing through the TX coil is determined by an equation:

$${I}_{TX} = \frac{1}{β} \sqrt{\frac{{C}_{TX}}{{L}_{TX}}} {V}_{C}^{**}$$

where I_{TX} indicates the current flowing through the TX coil; β indicates an attenuation coefficient; C_{TX} indicates a capacitance value of the TX coil, resonating with L_{TX}; L_{TX} indicates an inductance value of the TX coil; and V_{C}** indicates the second capacitor voltage.

According to a second aspect, an embodiment of the present application further provides a wireless charging chip, including the AC current sensor according to the first aspect and various possible implementations.

The embodiments of the present application provide an AC current sensor and a wireless charging chip. The AC current sensor has a current calibration function. Time constants of the differentiator circuit and the integrator circuit may be calibrated, without using a commercial current sensor to provide a reference current during the calibration process, so that the time constants are not affected by process changes. In this way, current detection accuracy after the calibration is not affected by an on-chip component parameter, current measurement accuracy is high, and a structure is compact, easy to be integrated.

### BRIEF DESCRIPTION OF THE DRAWINGS

To more clearly describe the technical solutions of the present application, the accompanying drawings for the embodiments are briefly illustrated below. Obviously, persons of ordinary skills in the art may also derive other accompanying drawings according to these accompanying drawings without an effective effort.

FIG. 1 is a schematic diagram illustrating a circuit structure of a conventional AC current sensor;

FIG. 2 is a schematic diagram illustrating an overall structure of an AC current sensor according to an embodiment of the present application;

FIG. 3 is a schematic diagram illustrating a structure of an integrator circuit in FIG. 2;

FIG. 4 is a schematic diagram illustrating a structure of a differentiator circuit in FIG. 2;

FIG. 5 is a schematic diagram illustrating structures of a first adjustable resistor in FIG. 3 and a second adjustable resistor in FIG. 4;

FIG. 6 is a schematic diagram illustrating a structure of a clock circuit according to an embodiment of the present application;

FIG. 7 is a schematic diagram illustrating an example of timing waveforms of signals output from a clock circuit shown in FIG. 6;

FIG. 8 is a schematic diagram illustrating a structure of a logic circuit according to an embodiment of the present application;

FIG. 9 is a schematic diagram illustrating structures of a first sample-and-hold circuit and a second sample-and-hold circuit according to an embodiment of the present application;

FIG. 10 is a schematic diagram illustrating a structure of a comparer according to an embodiment of the present application;

FIG. 11 is a schematic diagram illustrating an output result of a comparator shown in FIG. 10;

FIG. 12 is a schematic diagram illustrating overall timing logic of a calibration circuit according to an embodiment of the present application;

FIG. 13 is a schematic diagram illustrating structures of a first filter circuit and a second filter circuit in FIG. 2;

FIG. 14 is a schematic sequence diagram illustrating signal waveform timings of a second inductor voltage and a second capacitor voltage during a calibration process of an AC current sensor according to an embodiment of the present application; and

FIG. 15 is a schematic diagram illustrating a structure of a voltage measurement circuit according to an embodiment of the present application.

### DETAILED DESCRIPTION OF THE EMBODIMENTS

To make objectives, technical solutions, and advantages of the present application more clear, the implementations of the present application are further described in detail with reference to the accompanying drawings.

A conventional AC current sensor is first introduced below.

FIG. 1 is a schematic diagram illustrating a circuit structure of a conventional AC current sensor. Referring to FIG. 1, a TX coil disposed in a transmitter typically includes an inductor L_{TX} and a capacitor C_{TX} that are connected in series.

In an AC current sensor shown in a structure a, a known resistor is inserted to serve as a detection resistor R_{SEN}. A current I_{TX} of the TX coil is calculated by measuring a voltage V_{SEN} across the detection resistor R_{SEN}. However, a resistance value introduced by this method usually has a manufacturing deviation of 10%˜15%, not only affecting current measurement accuracy, but also resulting in power losses and efficiency being reduced.

In an AC current sensor shown in a structure b, a secondary coil may is used to be close to an inductor L_{TX} and a current of the secondary coil is measured. Since the current of the secondary coil is in direct proportion to a current of a primary coil, a current of the inductor L_{TX} may be obtained according to the current of the secondary coil and the proportion, and may be used as the measured current I_{TX} of the TX coil. However, by this method, costs and an area may be increased, and integration cannot be implemented, greater measurement deviations occurring.

In an AC current sensor shown in a structure c, a SensFET device constructed to be connected in parallel with a power transistor. A current flowing through the SensFET device is detected, and then a current flowing through the transistor is determined according to widths of the transistor and the SensFET device. However, in this method, size mismatch of the transistor may reduce current detection accuracy.

An AC current sensor shown in a structure d is widely applicable to DC-DC converters (Direct Current-Direct Current converter). However, when there are a plurality of TX coils in the transmitter, coupling between a RX coil and the TX coil may affect the current detection accuracy.

Through an implementation structure of the conventional AC current sensor, it may be found that there are, for the conventional AC current sensor, technical problems of low accuracy in measuring the current of the TX coil and being difficult for integration. To resolve the technical problems of the conventional AC current sensor, the present application discloses an AC current sensor according to the following embodiments. The AC current sensor according to the embodiments of the present application is applicable to a wireless charging device to measure a current flowing through a corresponding TX coil. It should be noted that the wireless charging device may be provided with one TX coil or a plurality of TX coils, which is not specifically limited in the embodiments of the present application.

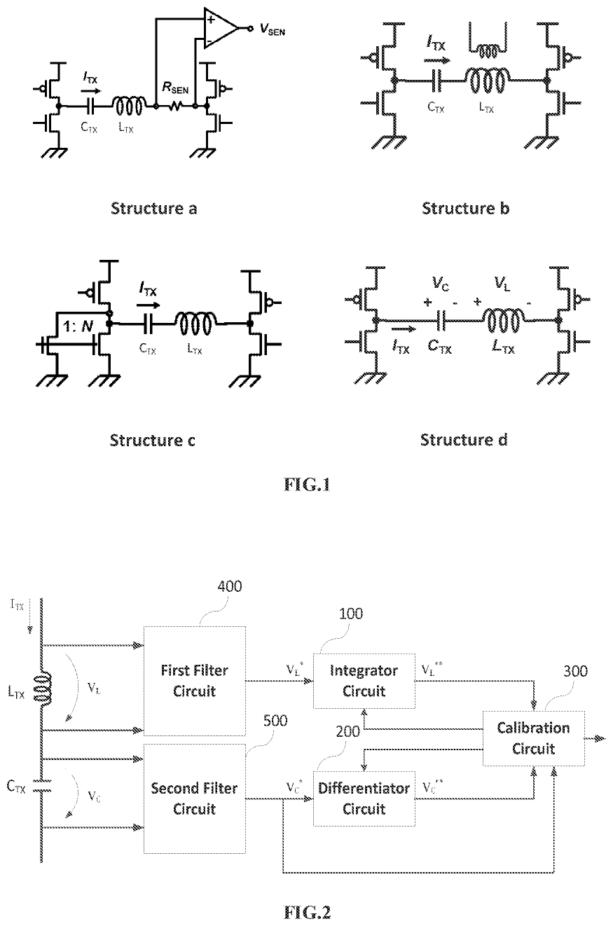

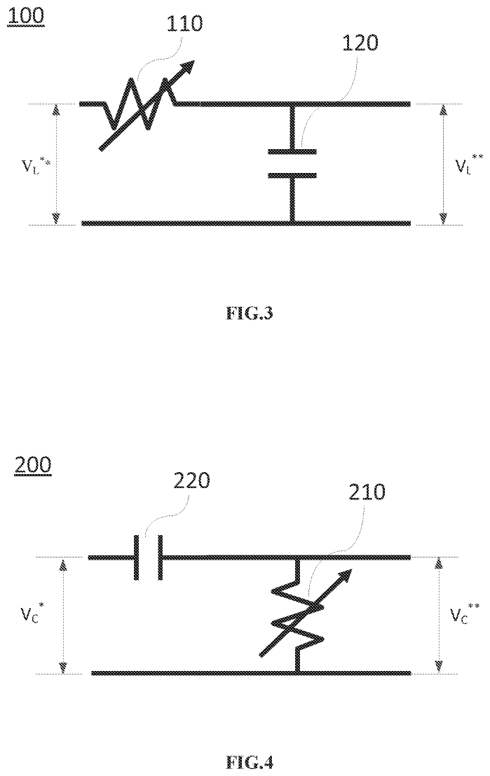

FIG. 2 is a schematic diagram illustrating an overall structure of an AC current sensor according to an embodiment of the present application. As shown in FIG. 2, the AC current sensor according to this embodiment of the present application includes an integrator circuit 100, a differentiator circuit 200, and a calibration circuit 300. The integrator circuit 100 is configured for receiving of a first inductor voltage V_{L}* through a first input terminal of the integrator circuit 100, and perform integration on the first inductor voltage V_{L}* to generate a second inductor voltage V_{L}**. The first inductor voltage V_{L}* is a voltage obtained by performing filtering processing on a voltage V_{L} across an inductor L_{TX} in a TX coil. The integrator circuit 100 includes a first adjustable resistor. In some embodiments, the filtering processing may be performed on the voltage V_{L} across the inductor L_{TX} through a first filter circuit 400.

The differentiator circuit 200 is configured for receiving of a first capacitor voltage V_{C}* through a first input terminal of the differentiator circuit 200, and perform differentiation on the first capacitor voltage V_{C}* to generate a second capacitor voltage V_{C}**. The first capacitor voltage V_{C}* is a voltage obtained by performing filtering processing on a voltage V_{C} across a capacitor C_{TX} in the TX coil. The differentiator circuit 200 includes a second adjustable resistor. In some embodiments, the filtering processing may be performed on the voltage V_{C} across the capacitor C_{TX} through a second filter circuit 500.

The calibration circuit 300 is configured to generate a clock signal based on the first capacitor voltage V_{C}*, simultaneously adjust resistance values of the first adjustable resistor and the second adjustable resistor according to the clock signal, and compare a third inductor voltage V_{L}*** with a third capacitor voltage V_{C}*** in a real-time manner until the third inductor voltage V_{L}*** is equal to the third capacitor voltage V_{C}*** to complete calibration. The third inductor voltage V_{L}*** is obtained by performing peak sampling on the second inductor voltage V_{L}**, and the third capacitor voltage V_{C}*** is obtained by performing peak sampling on the second capacitor voltage V_{C}**. After the calibration is completed, the second capacitor voltage V_{C}** output from the differentiator circuit 200 is to be converted into a current I_{TX} flowing through the TX coil according to a preset conversion relationship.

As such, the AC current sensor according to this embodiment of the present application has a current calibration function. Time constants of the differentiator circuit and the integrator circuit may be calibrated, without using a commercial current sensor to provide a reference current during the calibration process, so that the time constants are not affected by process changes. In this way, current detection accuracy after the calibration is not affected by an on-chip component parameter, current measurement accuracy is high, and a structure is compact, easy to be integrated.

Various circuits of the AC current sensor according to this embodiment of the present application are first introduced below.

FIG. 3 is a schematic diagram illustrating a structure of an integrator circuit in FIG. 2. As shown in FIG. 3, in some embodiments, the integrator circuit 100 may include a first adjustable resistor 110 and a first capacitor 120 connected in series to the first adjustable resistor 110, wherein an end of the first adjustable resistor 110 away from the first capacitor 120 and an end of the first capacitor 120 away from the first adjustable resistor 110 are together configured as a first input terminal of the integrator circuit 100, and a voltage across the first capacitor 120 is configured as the second inductor voltage V_{L}**. In other embodiments, the integrator circuit 100 may also adopt another implementation structure, for example, including a first adjustable resistor 110, a first capacitor 120, a parallel resistor, and an operational amplifier. One terminal of the first adjustable resistor 110 is configured as the first input terminal of the integrator circuit 100, and the other terminal of the first adjustable resistor 110 is coupled to a negative input terminal of the operational amplifier. The first capacitor 120 is connected in parallel between the negative input terminal and an output terminal of the operational amplifier. The first capacitor 120 is further connected in parallel with the parallel resistor. The operational amplifier is configured to have a positive input terminal through which a division voltage signal is received, and the output terminal through which the second inductor voltage V_{L}** is output. A specific structure of the integrator circuit 100 is not limited in the embodiments of the present application.

FIG. 4 is a schematic diagram illustrating a structure of a differentiator circuit in FIG. 2. As shown in FIG. 4, in some embodiments, the differentiator circuit 200 may include a second adjustable resistor 210 and a second capacitor 220 connected in series to the second adjustable resistor 210, wherein an end of the second adjustable resistor 210 away from the second capacitor 220 and an end of the second capacitor 220 away from the second adjustable resistor 210 are together configured as a first input terminal of the differentiator circuit 200, and a voltage across the second adjustable resistor 210 is configured as the second capacitor voltage V_{C}**. In other embodiments, the differentiator circuit 200 may also adopt another implementation structure, for example, including a parasitic resistor, a second capacitor 220, a second adjustable resistor 210, a shunt capacitor, and an operational amplifier. One terminal of the parasitic resistor is configured as the first input terminal of the differentiator circuit 200, and the other terminal of the parasitic resistor is connected in series to the second capacitor 220, and is coupled to a negative input terminal of the operational amplifier. The second adjustable resistor 210 is connected in parallel between the negative input terminal and an output terminal of the operational amplifier. The second adjustable resistor 210 is further connected in parallel with the shunt capacitor. the operational amplifier is configured to have a positive input terminal through which a division voltage signal is received, and the output terminal through which the second capacitor voltage V_{C}** is output. A specific structure of the differentiator circuit 200 is not limited in the embodiments of the present application.

FIG. 5 is a schematic diagram illustrating structures of a first adjustable resistor in FIG. 3 and a second adjustable resistor in FIG. 4. As shown in FIG. 5, in the embodiments of the present application, the first adjustable resistor 110 and the second adjustable resistor 210 have a same structure, and each include a fixed resistor 111 and a plurality of controllable resistors 112 that are connected in series, and a plurality of adjustable switches 113. A resistance value of each of the controllable resistors 112 is in a preset proportion to a resistance value of the fixed resistor 111. In an example, as shown in FIG. 5, a number of the controllable resistors 112 may be 5, with resistance values of Rᵤ, Rᵤ/2, Rᵤ/4, Rᵤ/8, and Rᵤ/16, wherein Rᵤ is the resistance value of the fixed resistor 111. In this way, the plurality of controllable resistors 112 may form various combinations. The plurality of adjustable switches 113 are in one-to-one correspondence to the plurality of controllable resistors 112. The adjustable switches 113 are connected in parallel across the corresponding controllable resistors 112. The adjustable switch 113 includes a control input terminal for receiving of a switch control signal (such as SW4, SW3, SW2, SW1, or SW0), wherein the adjustable switch 113 is turned on or off under control of the switch control signal. In some embodiments, the adjustable switch 113 may be a transistor, specifically, may be an N-type MOS transistor (NMOS transistor). In an example, as shown in FIG. 5, a total resistance value of the first adjustable resistor 110 or the second adjustable resistor 210 is implemented by various combinations of Rᵤ, Rᵤ/2, Rᵤ/4, Rᵤ/8, and Rᵤ/16. For example, if the switch control signal SW4 for the adjustable switch 113 corresponding to a first controllable resistor 112 is at a low level and the respective switch control signals SW3, SW2, SW1, and SW0 of the adjustable switches 113 corresponding to second, third, fourth, and fifth controllable resistors 112 are all at high levels, the adjustable switch 113 corresponding to the first controllable resistor 112 is turned off and the respective adjustable switches 113 corresponding to the second, the third, the fourth, and the fifth controllable resistors 112 are turned on. In this case, the first adjustable resistor 110 or the second adjustable resistor 210 has a the total resistance value satisfying R=R_{U}+R_{U}. In this way, both the first adjustable resistor 110 and the second adjustable resistor 210 are 5-bit binary weighted resistor arrays.

In some embodiments, the calibration circuit according to the embodiments of the present application may include a clock circuit, a logic circuit, a first sample-and-hold circuit, a second sample-and-hold circuit, and a comparer.

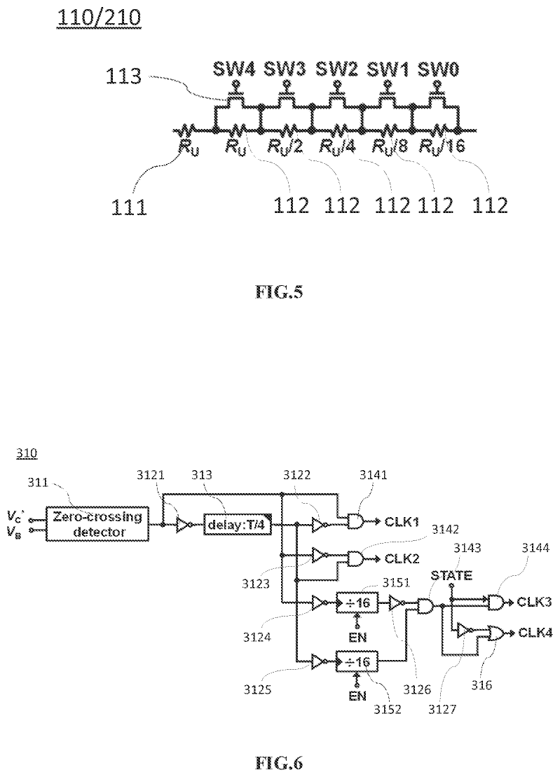

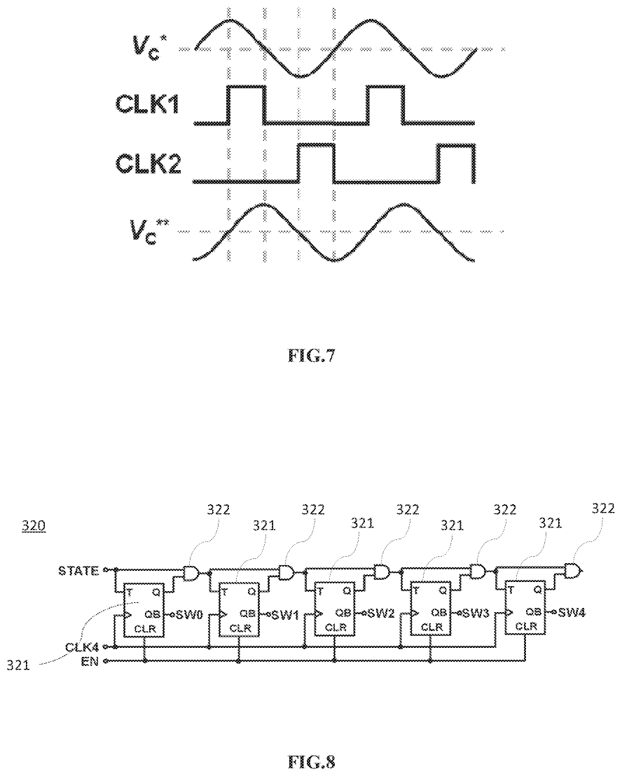

FIG. 6 is a schematic diagram illustrating a structure of a clock circuit according to an embodiment of the present application. A clock circuit 310 is configured to generate a first clock signal CLK1, a second clock signal CLK2, a third clock signal CLK3, and a fourth clock signal CLK4 based on the first capacitor voltage V_{c}*. FIG. 7 is an exemplary schematic diagram illustrating timing waveforms of signals output from a clock circuit shown in FIG. 6.

As shown in FIG. 6, in some embodiments, the clock circuit 310 may include a first zero-crossing detector 311, a first inverter 3121, a second inverter 3122, a third inverter 3123, a fourth inverter 3124, a fifth inverter 3125, a sixth inverter 3126, a seventh inverter 3127, a delayer 313, a first AND gate circuit 3141, a second AND gate circuit 3142, a third AND gate circuit 3143, a fourth AND gate circuit 3144, a first signal-frequency pickup circuit 3151, a second signal-frequency pickup circuit 3152, and an OR gate circuit 316. The first capacitor voltage V_{c}* and a division voltage signal V_{B} are input into the first zero-crossing detector 311. An output terminal of the first zero-crossing detector 311 is coupled to an input terminal of the first inverter 3121 and a first input terminal of the first AND gate circuit 3141, respectively. An output terminal of the first inverter 3121 is coupled to an input terminal of the delayer 313. An output terminal of the delayer 313 is coupled to an input terminal of the second inverter 3122, an input terminal of the fifth inverter 3125, and a second input terminal of the second AND gate circuit 3142, respectively. The input terminal of the first inverter 3121 is further coupled to an input terminal of the third inverter 3123 and an input terminal of the fourth inverter 3124, respectively. An output terminal of the second inverter 3122 is coupled to a second input terminal of the first AND gate circuit 3141. An output terminal of the third inverter 3123 is coupled to a first input terminal of the second AND gate circuit 3142. An output terminal of the fourth inverter 3124 is coupled to an input terminal of the first signal-frequency pickup circuit 3151. An output terminal of the first signal-frequency pickup circuit 3151 is coupled to an input terminal of the sixth inverter 3126. An output terminal of the sixth inverter 3126 is coupled to a first input terminal of the third AND gate circuit 3143. An output terminal of the fifth inverter 3125 is coupled to an input terminal of the second signal-frequency pickup circuit 3152. An output terminal of the second signal-frequency pickup circuit 3152 is coupled to a second input terminal of the third AND gate circuit 3143. An output terminal of the third AND gate circuit 3143 is coupled to a second input terminal of the fourth AND gate circuit 3144 and a second input terminal of the OR gate circuit 316, respectively. A state signal STATE of the clock circuit 310 is input into a first input terminal of the fourth AND gate circuit 3144 and is input into a first input terminal of the OR gate circuit 316 through the seventh inverter 3127. An enable signal EN is input into the first signal-frequency pickup circuit 3151 and the second signal-frequency pickup circuit 3152, respectively. Finally, the first AND gate circuit 3141 outputs the first clock signal CLK1 through an output terminal thereof, the second AND gate circuit 3142 outputs the second clock signal CLK2 through an output terminal thereof, the fourth AND gate circuit 3144 outputs the third clock signal CLK3 through an output terminal thereof, and the OR gate circuit 316 outputs the fourth clock signal CLK4 through an output terminal thereof. The delayer 313 is configured to delay by one quarter of a cycle, and the first signal-frequency pickup circuit 3151 and the second signal frequency-pickup circuit 3152 are configured to pickup one sixteenth of a signal frequency. The division voltage signal V_{B} may be acquired by provision of an additional voltage divider circuit, details of which are not described herein. As an example, FIG. 7 shows a diagram illustrating signal timing waveforms of a first clock signal CLK1 and a second clock signal CLK2 that are generated by a clock circuit 310 based on a first capacitor voltage V_{c}*, and a second capacitor voltage V_{C}** generated by differentiating a first capacitor voltage V_{C}* by a differentiator.

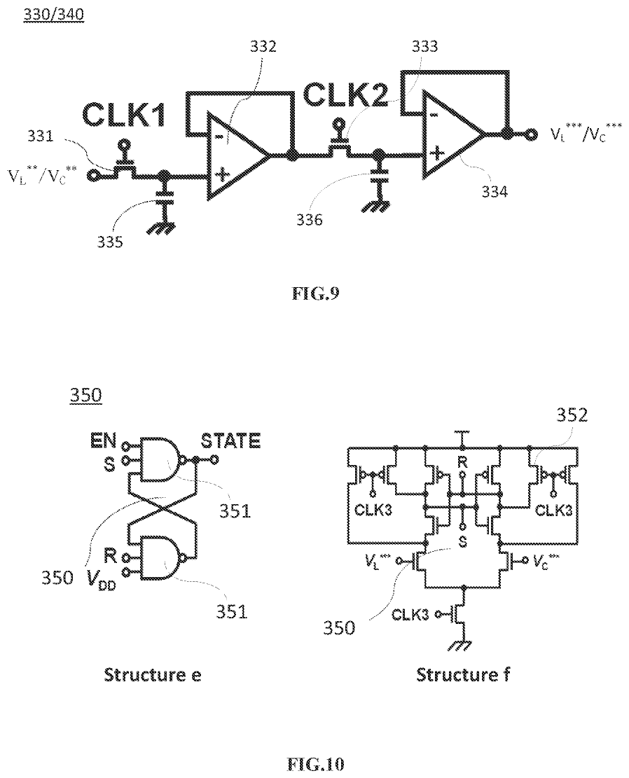

FIG. 8 is a schematic diagram illustrating a structure of a logic circuit according to an embodiment of the present application. An output terminal of a logic circuit 320 is coupled to a second input terminal of the integrator circuit and a second input terminal of the differentiator circuit, respectively. The logic circuit 320 is configured to simultaneously adjust the resistance values of the first adjustable resistor and the second adjustable resistor according to the fourth clock signal CLK4.

As shown in FIG. 8, in some embodiments, the logic circuit 320 may include a plurality of flip-flops 321 and a plurality of logic gates 322, which are sequentially connected. The plurality of flip-flops 321 and the plurality of logic gates 322 are in one-to-one correspondence to the plurality of adjustable switches of the first adjustable resistor or the plurality of adjustable switches of the second adjustable resistor. A first input terminal of the logic gate 322 is coupled to a first output terminal (Q terminal) of a corresponding flip-flop 321. An output terminal of the logic gate 322 is coupled to a second input terminal of a next logic gate 322 and a first input terminal of a flip-flop 321 corresponding to the next logic gate 322, respectively. A second input terminal of a first one of the logic gates 322 and a first input terminal (T terminal) of a corresponding flip-flop 321 are configured for receiving of the state signal STATE output from the comparator. A second input terminal of each flip-flop 321 is configured for receiving of the fourth clock signal CLK4. A third input terminal (CLR terminal) of each flip-flop 321 is configured for receiving of a first enable signal EN. A second output terminal (QB terminal) of each flip-flop 321 is coupled to the control input terminal of the corresponding adjustable switch. The second output terminal (QB terminal) of each flip-flop 321 is configured for outputting of the switch control signal for the corresponding adjustable switch. For example, referring to FIG. 8 in conjunction with FIG. 5, a first one of the flip-flops 321 outputs, through a second output terminal thereof, the switch control signal SW0 for the adjustable switch corresponding to a fifth controllable resistor; a second one of the flip-flops 321 outputs, through a second output terminal thereof, the switch control signal SW1 for the adjustable switch corresponding to a fourth controllable resistor; a third one of the flip-flops 321 outputs, through a second output terminal thereof, the switch control signal SW2 for the adjustable switch corresponding to a third controllable resistor; a fourth one of the flip-flops 321 outputs, through a second output terminal thereof, the switch control signal SW3 for the adjustable switch corresponding to a second controllable resistor; and a fifth one of the flip-flops 321 outputs, through a second output terminal thereof, the switch control signal SW4 for the adjustable switch corresponding to a first controllable resistor.

FIG. 9 is a schematic diagram illustrating structures of a first sample-and-hold circuit and a second sample-and-hold circuit according to an embodiment of the present application. A first input terminal of a first sample-and-hold circuit 330 in this embodiment of the present application is coupled to an output terminal of the integrator circuit. The first sample-and-hold circuit 330 is configured to perform peak sampling on the second inductor voltage V_{L}** according to the first clock signal CLK1 and the second clock signal CLK2, to obtain the third inductor voltage V_{L}***. A first input terminal of a second sample-and-hold circuit 340 is coupled to an output terminal of the differentiator circuit. The second sample-and-hold circuit 340 is configured to perform peak sampling on the second capacitor voltage V_{C}** according to the first clock signal CLK1 and the second clock signal CLK2, to obtain the third capacitor voltage V_{C}***.

As shown in FIG. 9, in some embodiments, the first sample-and-hold circuit 330 and the second sample-and-hold circuit 340 have a same structure, and each include a first flip-flop switch 331, a first operational amplifier 332, a second flip-flop switch 333, and a second operational amplifier 334. A first terminal of the first flip-flop switch 331 is configured for receiving of the corresponding second inductor voltage V_{L}** or second capacitor voltage V_{C}**. A second terminal of the first flip-flop switch 331 is coupled to a positive input terminal (+) of the first operational amplifier 332. A negative input terminal (−) of the first operational amplifier 332 is coupled to an output terminal of the first operational amplifier 332. The output terminal of the first operational amplifier 332 is further coupled to a first terminal of the second flip-flop switch 333. A second terminal of the second flip-flop switch 333 is coupled to a positive input terminal (+) of the second operational amplifier 334. A negative input terminal (−) of the second operational amplifier 334 is coupled to an output terminal of the second operational amplifier 334. The output terminal of the second operational amplifier 334 is configured for outputting of the corresponding third inductor voltage V_{L}*** or third capacitor voltage V_{C}***. The second terminal of the first flip-flop switch 331 is further connected to a first ground capacitor 335. The second terminal of the second flip-flop switch 333 is further connected to a second ground capacitor 336. A third terminal of the first flip-flop switch 331 is configured for receiving of the first clock signal CLK1. A third terminal of the second flip-flop switch 333 is configured for receiving of the second clock signal CLK2. The first flip-flop switch 331 and the second flip-flop switch 333 may be transistors. The first ground capacitor 335 and the second ground capacitor 336 are used for filtering. In this way, in the embodiments of the present application, because V_{C}** (or V_{L}**) is an alternating current, the sample-and-hold circuit (S&H for short) may store a peak value thereof as V_{C}*** (or V_{L}***) at an appropriate time. In other embodiments, the first sample-and-hold circuit 330 and the second sample-and-hold circuit 340 may also use another structure, and for example, may include a first operational amplifier 332, a second operational amplifier 334, a second flip-flop switch 333, and a ground capacitor. A positive input terminal of the first operational amplifier 332 is configured for receiving of the corresponding second inductor voltage V_{L}** or second capacitor voltage V_{C}**. A negative input terminal of the first operational amplifier 332 is coupled to a negative input terminal of the second operational amplifier 334 through an equivalent resistor. An output terminal of the first operational amplifier 332 is coupled to a first terminal of the second flip-flop switch 333. A second terminal of the second flip-flop switch 333 is coupled to a positive input terminal of the second operational amplifier 334. The second terminal of the second flip-flop switch 333 is further connected to the ground capacitor. A third terminal of the second flip-flop switch 333 is configured for receiving of the second clock signal CLK2. An output terminal of the second operational amplifier 334 is configured for outputting of the corresponding third inductor voltage V_{L}*** or third capacitor voltage V_{C}***. A structure of a sampling circuit is not specifically limited in the embodiments of the present application.

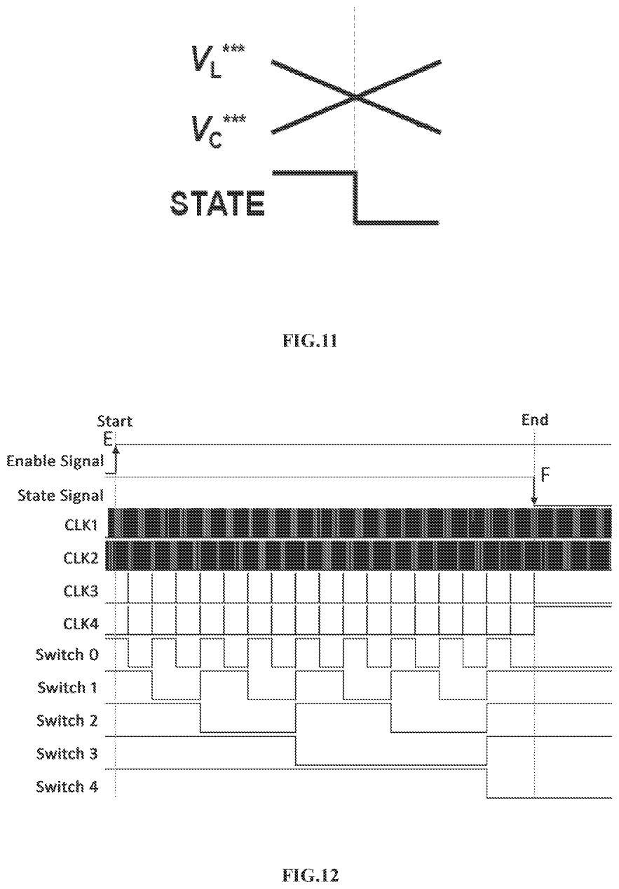

FIG. 10 is a schematic diagram illustrating a structure of a comparer according to an embodiment of the present application. In this embodiment of the present application, a first input terminal of a comparer 350 is coupled to an output terminal of the first sample-and-hold circuit, and a second input terminal of the comparer 350 is coupled to an output terminal of the second sample-and-hold circuit. The comparer 350 is configured to compare the third inductor voltage V_{L}*** with the third capacitor voltage V_{C}*** in a real-time manner according to the third clock signal CLK3, and output a comparison result. The comparison result is in a form of a state signal STATE, and is used to indicate whether the third inductor voltage V_{L}*** is equal to the third capacitor voltage V_{C}***.

As shown in FIG. 10, in some embodiments, a structure e is a logical structure of the comparer 350, and a structure f is a specific design structure of the comparer 350, both of which represent a same structure, S indicating an SET terminal, R indicating a RESET terminal, EN indicating an enable terminal, V_{DD} indicating a power input terminal, STATE indicating the output state signal, 351 indicating a NAND gate, and 352 indicating a transistor.

FIG. 11 is a schematic diagram illustrating an output result of a comparator shown in FIG. 10. As shown in FIG. 11, because the resistance values of both the first adjustable resistor and the second adjustable resistor are minimum at an initial time, it is satisfied that the V_{L}***>the V_{C}***, and the comparison result STATE output from the comparer is at a high level. As the resistance values of the first adjustable resistor and the second adjustable resistor increase, the V_{L}*** decreases while the V_{C}*** increases, until the V_{L}*** is less than the V_{C}***, and the comparison result STATE output from the comparer is at a low level.

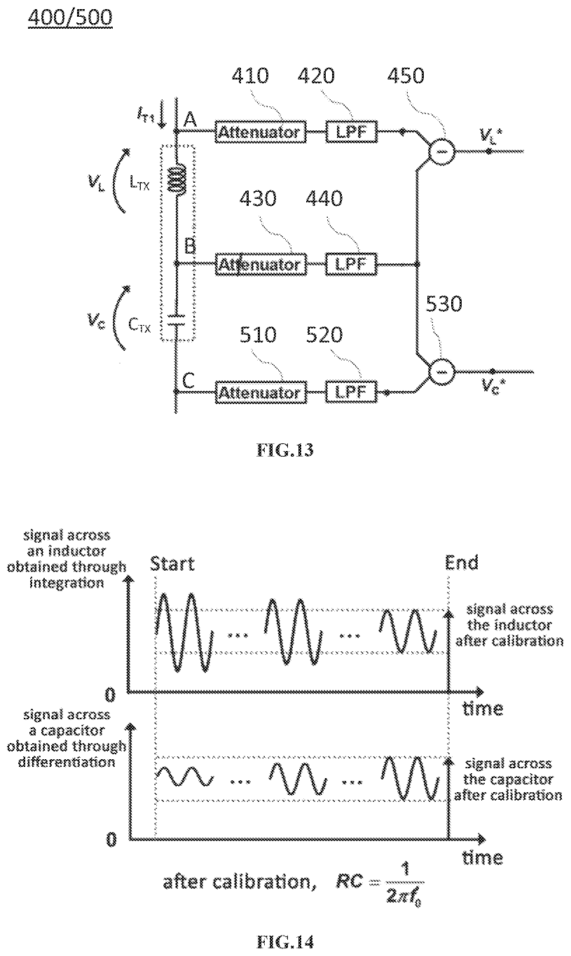

FIG. 12 is a schematic diagram illustrating overall timing logic of a calibration circuit according to an embodiment of the present application. As shown in FIG. 12, CLK1 indicates a clock signal with a frequency of f₀. At a start point E, the enable signal EN is at a low level and the logic circuit is driven to be in a reset state. When the state signal STATE output from the comparator is at a high level, the switch control signals SW0-SW4 received by the adjustable switches (that is, Switch 0-Switch 4) are all at high levels, and calibration starts as the enable signal EN becomes high. The comparator compares the V_{L}*** with the V_{C}*** when a clock signal CLK3 is at a high level, and it is satisfied that the V_{L}***>the V_{C}***, because the resistance values R of the first adjustable resistor and the second adjustable resistor are minimum. The logic circuit is toggled at a falling edge of a clock signal CLK4, so that the switch control signals SW0-SW4 continue to count down. It need take time for the integrator circuit and the differentiator circuit to recover to a stable state after the resistance value R changes. Therefore, a frequency of the clock signal CLK4 is set to f₀/16. As the resistance value R increases, the V_{L}*** decreases while the V_{C}*** increases, until the V_{L}*** is less than the V_{C}***. In this case, the state signal STATE output from the comparator is at a low level, and the calibration ends at the falling edge. After the calibration ends, the clock signal CLK3 and the clock signal CLK4 at a point F are pulled to a low level and a high level, respectively. The comparator and the logic circuit stop working, and the STATE remains a high level until measurement is completed.

FIG. 13 is a schematic diagram illustrating structures of a first filter circuit and a second filter circuit in FIG. 2. In this embodiment of the present application, the first filter circuit is configured to perform attenuation, low-pass filtering, and subtraction on the voltage V_{L} across the inductor L_{TX} in the TX coil to obtain the first inductor voltage V_{L}*. The second filter circuit is configured to perform attenuation, low-pass filtering, and subtraction on the voltage V_{C} across the capacitor C_{TX} in the TX coil to obtain the first capacitor voltage V_{C}*.

As shown in FIG. 13, in some embodiments, the first filter circuit includes a first attenuator 410, a first low-pass filter (LPF) 420, a second attenuator 430, a second low-pass filter (LPF) 440, and a first subtractor circuit 450. Specifically, after a voltage at a first wiring point A is attenuated through the first attenuator 410 and is low-pass filtered through the first low-pass filter 420, frequency components other than a frequency f₀ is removed, and an obtained signal is input into the first subtractor circuit 450. After a voltage at a second wiring point B is attenuated through the second attenuator 430 and is low-pass filtered through the second low-pass filter 440, frequency components other than the frequency f₀ is removed, and an obtained signal is also input into the first subtractor circuit 450. Subtraction is performed on the two voltage signals to obtain the first inductor voltage V_{L}*. The second wiring point B is located between the inductor L_{TX} and the capacitor C_{TX}, and the first wiring point A is located on one side of the inductor L_{TX}.

The second filter circuit includes a third attenuator 510, a third low-pass filter (LPF) 520, a fourth attenuator, a fourth low-pass filter (LPF), and a second subtractor circuit 530. The fourth attenuator and the fourth low-pass filter (LPF) may be replaced with the second attenuator 430 and the second low-pass filter (LPF) 440, respectively. In other words, voltages at the second wiring point B may be merged into one for filtering processing. Specifically, after the voltage at the second wiring point B is attenuated through the second attenuator 430 and is low-pass filtered through the second low-pass filter 440, the frequency components other than the frequency f₀ is removed, and the obtained signal is input into the second subtractor circuit 530. After a voltage at a third wiring point C is attenuated through the third attenuator 510 and is low-pass filtered through the third low-pass filter 520, frequency components other than the frequency f₀ is removed, and an obtained signal is also input into the second subtractor circuit 530. Subtraction is performed on the two voltage signals to obtain the first capacitor voltage V_{C}*. The third wiring point C is located on the other side of the capacitor C_{TX}.

In the embodiments of the present application, all attenuators in the first filter circuit and the second filter circuit have the same attention coefficients, all of which being B. In this way, the low-pass filter is configured to remove any frequency component except the f₀. To ensure that losses of frequency component at f₀ are negligible and frequency components at 3f₀ are reduced sufficiently, a fifth-order Chebyshev filter may be selected, where the losses at f₀ are included. Because a voltage across the TX coil and the current flowing through the TX coil are both affected by B, changes of β would not reduce reliability of circuit performance.

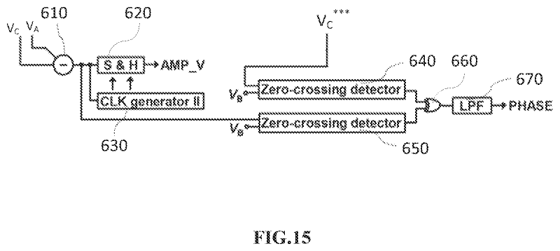

FIG. 14 is a schematic sequence diagram illustrating signal waveform timings of a second inductor voltage and a second capacitor voltage during a calibration process of an AC current sensor according to an embodiment of the present application. As shown in FIG. 14, for on-chip implementation, time constants RC used for the differentiator circuit and the integrator circuit are the same. However, as the time constant RC varies with the process, current detection accuracy may be decreased. Therefore, in order to compensate for changes in a resistance R of the differentiator circuit and a capacitance C of the differentiator circuit in the current sensor, both the voltage V_{L} across the inductor and the voltage V_{C} across the capacitor in the TX coil are measured. Calibration on adjustable resistors R in the differentiator circuit and the integrator circuit is implemented by a 5-digit adjustable resistor, so that it is satisfied that the second inductor voltage V_{L}** is equal to the second capacitor voltage V_{C}**. The second inductor voltage signal V_{L}** across the inductor obtained through integration gradually decreases during the calibration process, while the second capacitor voltage signal V_{C}** across the capacitor obtained through differentiation gradually increases during the calibration process, and finally both of them become equal to each other. After the calibration, the time constant RC may be determined according to the following equation (1):

$$RC = \frac{1}{2 π {f}_{0}} = \frac{1}{{ω}_{0}} \qquad Equation ( 1 )$$

In the equation (1), f₀ indicates frequencies of the first inductor voltage V_{L}* and the first capacitor voltage V_{C}*, and ω₀ indicates an angular frequency for the L_{TX} to resonate.

In this embodiment of the present application, after the time constant RC is calibrated, the second capacitor voltage V_{C}** output from the differentiator circuit may be used to be converted into the current flowing through the TX coil according to a preset conversion relationship. Specifically, it may be determined according to the following equation (2):

$${I}_{TX} = \frac{1}{β} \sqrt{\frac{{C}_{TX}}{{L}_{TX}}} {V}_{C}^{**} \qquad Equation ( 2 )$$

In the equation (2), I_{TX} indicates the current flowing through the TX coil; β indicates an attenuation coefficient; C_{TX} indicates a capacitance value of the TX coil, resonating with L_{TX}; L_{TX} indicates an inductance value of the TX coil; and V_{C}** indicates the second capacitor voltage.

The equation (2) may be deduced from the following equation (3):

$$2 π {f}_{0} = {( {L}_{TX} {C}_{TX} )}^{- \frac{1}{2}} \qquad Equation ( 3 )$$

$${V}_{L} = {I}_{TX} 2 π {f}_{0} {L}_{TX} \to {V}_{L}^{*} = {V}_{L} β \to {V}_{L}^{**} = {V}_{L}^{*} = {V}_{L}^{*} \frac{1}{RC 2 π {f}_{0}} \to {V}_{L}^{** *}$$

$${V}_{C} = {I}_{TX} 2 π {f}_{0} {C}_{TX} \to {V}_{C}^{*} = {V}_{C} β \to {V}_{C}^{**} = {V}_{C}^{*} RC 2 π {f}_{0} \to {V}_{C}^{** *}$$

In the equation (3), I_{TX} indicates the current flowing through the TX coil; β indicates an attenuation coefficient; C_{TX} indicates a capacitance value of the TX coil, resonating with L_{TX}; L_{TX} indicates an inductance value of the TX coil; f₀ indicates frequencies of the first inductor voltage V_{L}* and the first capacitor voltage V_{C}*; V_{C} indicates a voltage across the C_{TX}; V_{L} indicates a voltage across the L_{TX}; V_{C}** indicates the second capacitor voltage; V_{L}** indicates the second inductor voltage; V_{C}*** indicates the third capacitor voltage; V_{L}*** indicates the third inductor voltage; and RC indicates a time constant.

After the calibration, if it is satisfied that V_{C}***=V_{L}***, the equation (2) may be obtained. The calibrated time constant RC may be calculated based on f₀. As the C_{TX} and the L_{TX} are known, and an amplitude of the V_{C}** is obtained by measuring the V_{C}***=***, accurate I_{TX} may be obtained. After the calibration, total resistance values of the integrator circuit and the differentiator circuit remain unchanged, and the AC current sensor starts to operate.

In addition, the AC current sensor according to the embodiments of the present application may also include a voltage measurement circuit, which may be configured to measure the voltage across the TX coil and phase information.

FIG. 15 is a schematic diagram illustrating a structure of a voltage measurement circuit according to an embodiment of the present application. As shown in FIG. 15, a voltage measurement circuit 600 includes a third subtractor circuit 610, a third sample-and-hold circuit (S&H) 620, a second clock circuit (CLK generator II) 630, a second zero-crossing detector 640, a third zero-crossing detector 650, an XOR gate 660, and a fifth low-pass filter (LPF) 670. After subtraction is performed on a voltage VA at the first wiring point A and a voltage V_{C} at the third wiring point C by the third subtractor circuit 610, the voltage across the TX coil is obtained, then passes through the third sample-and-hold circuit 620 to obtain AMP_V, and is input into both the second clock circuit 630 through an input terminal thereof and the third zero-crossing detector 650 through an input terminal thereof. A division voltage signal V_{B} is also input into the third zero-crossing detector 650 through an input terminal thereof. The division voltage signal V_{B} and the third capacitor voltage V_{C}*** are input into the second zero-crossing detector 640 together. After output of the second zero-crossing detector 640 and output of the third zero-crossing detector 650 pass through the XOR gate 660 and the fifth low-pass filter 670, phase information PHASE is obtained.

In this way, the AC current sensor according to this embodiment of the present application has a current calibration function. The time constants of the differentiator circuit and the integrator circuit may be calibrated, without using the commercial current sensor to provide the reference current during the calibration process, so that the time constants are not affected by process changes. In this way, the current detection accuracy after the calibration is not affected by the on-chip component parameter, the current measurement accuracy is high, and the structure is compact, easy to be integrated.

In addition, an embodiment of the present application also provides a wireless charging chip, including the AC current sensor in the foregoing embodiments of the present application. The wireless charging chip has a compact structure, a high integration degree, a small overall area, and high current detection accuracy that is not affected by an on-chip component parameter.

The present application is described above in detail with reference to specific implementations and exemplary examples. However, these descriptions should not be construed as limitation to the present application. A person skilled in the art should understand that, without departing from the spirit and the scope of the present application, various equivalent substitutions, modifications, or improvements may be made to the technical solutions and implementations of the present application, which shall all fall within the scope of the present application. The protection scope of the present application shall be subject to the following claims.

What is claimed is:

1. An AC current sensor, comprising:
an integrator circuit, configured to receive a first inductor voltage through a first input terminal of the integrator circuit, and perform integration on the first inductor voltage to generate a second inductor voltage, wherein the first inductor voltage is a voltage obtained by performing filtering processing on a voltage across an inductor in a TX coil, and the integrator circuit comprises a first adjustable resistor;
a differentiator circuit, configured to receive a first capacitor voltage through a first input terminal of the differentiator circuit, and perform differentiation on the first capacitor voltage to generate a second capacitor voltage, wherein the first capacitor voltage is a voltage obtained by performing filtering processing on a voltage across a capacitor in the TX coil, and the differentiator circuit comprises a second adjustable resistor; and
a calibration circuit, configured to generate a clock signal based on the first capacitor voltage, simultaneously adjust resistance values of the first adjustable resistor and the second adjustable resistor according to the clock signal, and compare a third inductor voltage with a third capacitor voltage in a real-time manner until the third inductor voltage is equal to the third capacitor voltage to complete calibration, wherein the third inductor voltage is obtained by performing peak sampling on the second inductor voltage, and the third capacitor voltage is obtained by performing peak sampling on the second capacitor voltage,
wherein after the calibration is completed, the second capacitor voltage output from the differentiator circuit is used to be converted into a current flowing through the TX coil according to a preset conversion relationship.

2. The AC current sensor according to claim 1, wherein the calibration circuit comprises:
a clock circuit, configured to generate a first clock signal, a second clock signal, a third clock signal, and a fourth clock signal based on the first capacitor voltage;
a logic circuit, having an output terminal coupled to a second input terminal of the integrator circuit and a second input terminal of the differentiator circuit, respectively, and configured to simultaneously adjust the resistance values of the first adjustable resistor and the second adjustable resistor according to the fourth clock signal;
a first sample-and-hold circuit, having a first input terminal coupled to an output terminal of the integrator circuit, and configured to perform peak sampling on the second inductor voltage according to the first clock signal and the second clock signal to obtain the third inductor voltage;
a second sample-and-hold circuit, having a first input terminal coupled to an output terminal of the differentiator circuit, and configured to perform peak sampling on the second capacitor voltage according to the first clock signal and the second clock signal to obtain the third capacitor voltage; and
a comparer, having a first input terminal coupled to an output terminal of the first sample-and-hold circuit and a second input terminal coupled to an output terminal of the second sample-and-hold circuit, and configured to compare the third inductor voltage with the third capacitor voltage in a real-time manner according to the third clock signal, and output a comparison result for indicating whether the third inductor voltage is equal to the third capacitor voltage.

3. The AC current sensor according to claim 2, wherein the first adjustable resistor and the second adjustable resistor have a same structure, each comprising:
a fixed resistor and a plurality of controllable resistors, which are connected in series, wherein a resistance value of each of the controllable resistors is in a preset proportion to a resistance value of the fixed resistor; and
a plurality of adjustable switches in one-to-one correspondence to the plurality of controllable resistors, wherein the adjustable switches each are connected in parallel across the corresponding controllable resistors, and each of the adjustable switches comprises a control input terminal for receiving of a switch control signal and is turned on or off under control of the switch control signal.

4. The AC current sensor according to claim 3, wherein the logic circuit comprises a plurality of flip-flops and a plurality of logic gates, which are sequentially connected, and the plurality of flip-flops and the plurality of logic gates are in one-to-one correspondence to the plurality of the adjustable switches of the first adjustable resistor or the plurality of adjustable switches of the second adjustable resistor;
wherein each of the logic gates has a first input terminal coupled to a first output terminal of a corresponding one of the flip-flops, a second input terminal, and an output terminal of the logic gate is respectively coupled to a second input terminal of a next one of the logic gates and a first input terminal of one of the flip-flops corresponding to the next logic gate, wherein a second input terminal of a first one of the logic gates and a first input terminal of a corresponding one of the flip-flops are configured for receiving of a state signal output from the comparator; and
wherein each of the flip-flops has the first input terminal, a second input terminal configured for receiving of the fourth clock signal, a third input terminal configured for receiving of a first enable signal, the first output terminal, and a second output terminal coupled to the control input terminal of the corresponding adjustable switch configured for outputting of the switch control signal for the corresponding adjustable switch.

5. The AC current sensor according to claim 2, wherein the first sample-and-hold circuit and the second sample-and-hold circuit have a same structure, each comprising a first flip-flop switch, a first operational amplifier, a second flip-flop switch, and a second operational amplifier;
wherein the first flip-flop switch has a first terminal configured for receiving of a corresponding second inductor voltage or second capacitor voltage, a second terminal coupled to a positive input terminal of the first operational amplifier, and a third terminal configured for receiving of the first clock signal; the first operational amplifier has the positive input terminal, a negative input terminal, and an output terminal to which the negative input terminal is coupled, the output terminal of the first operational amplifier being further coupled to a first terminal of the second flip-flop switch; the second flip-flop switch has the first terminal, a second terminal coupled to a positive input terminal of the second operational amplifier, and a third terminal configured for receiving of the second clock signal; and the second operational amplifier has the positive input terminal, a negative input terminal, and an output terminal to which the negative input terminal of the second operational amplifier is coupled, and the output terminal of the second operational amplifier is configured for outputting of a corresponding third inductor voltage or third capacitor voltage; and
wherein the second terminal of the first flip-flop switch is further connected to a first ground capacitor, and the second terminal of the second flip-flop switch is further connected to a second ground capacitor.

6. The AC current sensor according to claim 1, wherein the integrator circuit further comprises a first capacitor connected in series to the first adjustable resistor; and
an end of the first adjustable resistor away from the first capacitor and an end of the first capacitor away from the first adjustable resistor are together configured as the first input terminal of the integrator circuit, and a voltage across the first capacitor is configured as the second inductor voltage.

7. The AC current sensor according to claim 6, wherein the differentiator circuit further comprises a second capacitor connected in series to the second adjustable resistor; and
an end of the second adjustable resistor away from the second capacitor and an end of the second capacitor away from the second adjustable resistor are together configured as the first input terminal of the differentiator circuit, and a voltage across the second adjustable resistor is configured as the second capacitor voltage.

8. The AC current sensor according to claim 1, further comprising:
a first filter circuit, configured to perform attenuation, low-pass filtering, and subtraction on the voltage across the inductor in the TX coil, respectively, to obtain the first inductor voltage; and
a second filter circuit, configured to perform attenuation, low-pass filtering, and subtraction on the voltage across the capacitor in the TX coil, respectively, to obtain the first capacitor voltage.

9. The AC current sensor according to claim 8, wherein the current flowing through the TX coil is determined by an equation:
$${I}_{TX} = \frac{1}{β} \sqrt{\frac{{C}_{TX}}{{L}_{TX}}} {V}_{C}^{**}$$
wherein I_{TX} indicates the current flowing through the TX coil; β indicates an attenuation coefficient; C_{TX} indicates a capacitance value of the TX coil, resonating with L_{TX}; L_{TX} indicates an inductance value of the TX coil; and V_{C}** indicates the second capacitor voltage.

10. A wireless charging chip, comprising the AC current sensor according to claim 1.
